(19) United States
(12) Patent Application Publication
(10) Pub. No.: US 2024/0381537 A1
(43) Pub. Date: Nov. 14, 2024

(54) Plateable Single Layer Capacitor

(71) Applicant: KYOCERA AVX Components Corporation, Fountain Inn, SC (US)

(72) Inventors: Cory Nelson, Simpsonville, SC (US); Jessica Parry, Myrtle Beach, SC (US)

(21) Appl. No.: 18/632,413

(22) Filed: Apr. 11, 2024

Related U.S. Application Data
(60) Provisional application No. 63/501,161, filed on May 10, 2023.

(51) Int. Cl. H05K 1/18

(52) U.S. Cl. CPC H05K 1/185; H05K 2201/10015

(57) ABSTRACT

Single layer capacitors and circuit boards are provided. A circuit board can include a circuit board substrate having a mounting surface and a single layer capacitor at least partially embedded within the circuit board substrate. The single layer capacitor can include a first passivation layer formed over at least a portion of a first surface of a substrate, a first conductive layer formed over at least a portion of the first passivation layer, and a second conductive layer formed over at least a portion of a second surface of the substrate. A method for forming a single layer capacitor can include depositing a passivation layer over at least a portion of a substrate first surface, depositing a first conductive layer over at least a portion of the passivation layer, and depositing a second conductive layer over at least a portion of a substrate second surface, opposite the first surface.

### RELATED APPLICATION

The present application is based upon and claims priority to U.S. Provisional Patent Application Ser. No. 63/501,161, having a filing date of May 10, 2023, which is incorporated herein by reference.

### BACKGROUND OF THE INVENTION

Single layer capacitors (SLCs) provide a variety of benefits, such as temperature stability, generally high breakdown voltages, and low leakage currents. Generally, however, SLCs are relatively thin, which can hinder their usefulness in embeddable applications because embedded capacitors can require a thick layer of metal to allow for formation of one or more vias for connectivity without hitting or damaging a substrate layer of the capacitor. Accordingly, a need exists for improved SLCs, such as for embedding.

### SUMMARY OF THE INVENTION

In accordance with one embodiment of the present disclosure, a circuit board can include a circuit board substrate having a mounting surface and a single layer capacitor at least partially embedded within the circuit board substrate. The single layer capacitor can include a substrate having a first surface opposite a second surface, a first passivation layer formed over at least a portion of the first surface of the substrate, a first conductive layer formed over at least a portion of the first passivation layer, and a second conductive layer formed over at least a portion of the second surface of the substrate.

In accordance with another embodiment of the present disclosure, a single layer capacitor can include a substrate having a first surface and a second surface opposite the first surface, a first passivation layer formed over at least a portion of the first surface of the substrate, a first conductive layer formed over at least a portion of the first passivation layer, and a second conductive layer formed over at least a portion of the second surface of the substrate.

In accordance with still another embodiment of the present disclosure, a method for forming a single layer capacitor can include depositing a first passivation layer over at least a portion of a first surface of a substrate, depositing a first conductive layer over at least a portion of the first passivation layer, and depositing a second conductive layer over at least a portion of a second surface of the substrate, the second surface opposite the first surface.

### BRIEF DESCRIPTION OF THE DRAWINGS

A full and enabling disclosure of the present invention, including the best mode thereof, directed to one of ordinary skill in the art, is set forth more particularly in the remainder of the specification, which makes reference to the appended figures, in which:

FIG. 1 is a side view of a capacitor according to aspects of the present disclosure;

FIG. 2A illustrates a circuit board including a capacitor fully embedded therein according to aspects of the present disclosure;

FIG. 2B illustrates another circuit board including a capacitor fully embedded therein according to aspects of the present disclosure;

FIG. 2C illustrates a circuit board including a capacitor partially embedded therein according to aspects of the present disclosure;

FIG. 3A is a perspective view of a capacitor according to aspects of the present disclosure;

FIG. 3B is a side view of the capacitor of FIG. 3A;

FIG. 4 illustrates a circuit board including a capacitor fully embedded therein according to aspects of the present disclosure;

FIG. 5 is a flowchart of a method for forming a capacitor according to aspects of the present disclosure; and

FIG. 6 is a flowchart of another method for forming a capacitor according to aspects of the present disclosure.

Repeat use of reference characters in the present specification and drawings is intended to represent same or analogous features or elements of the invention.

### DETAILED DESCRIPTION OF REPRESENTATIVE EMBODIMENTS

It is to be understood by one of ordinary skill in the art that the present discussion is a description of exemplary embodiments only and is not intended as limiting the broader aspects of the present invention, which broader aspects are embodied in the exemplary construction.

Generally speaking, the present invention is directed to a single layer capacitor having a passivation layer. For example, the single layer capacitor (SLC or “capacitor” as used herein) can include a substrate, a passivation layer formed over at least a portion of a first surface of the substrate, a first conductive layer (or first electrode) formed over at least a portion of the passivation layer, and a second conductive layer (or second electrode) formed over at least a portion of a second surface of the substrate that is opposite the first surface of the substrate. A second passivation layer may be formed over the second surface of the substrate and the second conductive layer may be formed over the second passivation layer such that the second passivation layer is disposed between the second conductive layer and the substrate.

A passivation layer between the substrate and a conductive layer may allow plating of the conductive layer. More particularly, many embeddable capacitor applications require a relatively thick conductive layer to allow for via drilling for connectivity without hitting or damaging the substrate. A protective layer of dielectric (i.e., a passivation layer) would allow the wafer to be plated to get the required thickness of the conductive layer to protect the substrate. A passivation layer may be formed on each of a pair of opposite surfaces of the substrate or wafer to allow plating of a conductive layer on each of the pair of opposite surfaces.

Additionally, or alternatively, plated conductive layers or electrodes can allow the single layer capacitor to be a solderable component. Typical single layer capacitors, which do not have plated conductive layers or electrodes, are only wire bondable or connectable with epoxy. A single layer capacitor having plated conductive layers or electrodes may be soldered, e.g., to a circuit board or the like, which may expand possible applications of single layer capacitors.

In some embodiments, the substrate may be formed from a material having a dielectric constant (K) that is less than about 30 as determined in accordance with ASTM D2520-13 at an operating temperature of 25° C. and frequency of 500 MHZ, in some embodiments less than about 25, in some embodiments less than about 20, and in some embodiments less than about 15. However, in other embodiments, a material having a dielectric constant higher than 30 may be used to achieve higher frequencies and/or smaller components. For example, in such embodiments, the dielectric constant may range from about 30 to about 120, or greater as determined in accordance with ASTM D2520-13 at an operating temperature of 25° C. and frequency of 500 MHZ, in some embodiments from about 50 to about 100, and in some embodiments from about 70 to about 90.

In still other embodiments, the substrate may be formed from a material having a relatively high dielectric constant (K), such as from about 10 to about 40,000 in some embodiments from about 50 to about 30,000, and in some embodiments, from about 100 to about 20,000.

The substrate may generally have a low thermal conductivity, such as less than about 10 W/(m·K), in some embodiments less than about 5 W/(m·K), in some embodiments less than about 3 W/(m·K), in some embodiments less than about 2 W/(m·K), and in some embodiments less than about 1 W/(m·K), and in some embodiments, greater than about 0.1 W/(m·K). In other embodiments, however, the substrate may have a thermal conductivity greater than 10 W/(m·K).

The substrate may comprise one or more suitable ceramic materials. Suitable materials are generally electrically insulating and thermally conductive. For example, in some embodiments, the substrate may include sapphire, ruby, alumina (Al₂O₃), aluminum nitride (AlN), beryllium oxide (BeO), aluminum oxide (Al₂O₃), boron nitride (BN), silicon (Si), silicon carbide (SiC), silica (SiO₂), silicon nitride (Si₃N₄), gallium arsenide (GaAs), gallium nitride (GaN), zirconium dioxide (ZrO₂), mixtures thereof, oxides and/or nitrides of such materials, or any other suitable ceramic material. Additional example ceramic materials include barium titanate (BaTiO₃), calcium titanate (CaTiO₃), zinc oxide (ZnO), ceramics containing low-fire glass, or other glass-bonded materials. Dielectric materials such as diamond and cubic boron arsenide may be used as well.

Particular examples of the type of high dielectric material include, for instance, NPO (COG) (up to about 100), X7R (from about 3,000 to about 7,000), X7S, Z5U, and/or Y5V materials. It should be appreciated that the aforementioned materials are described by their industry-accepted definitions, some of which are standard classifications established by the Electronic Industries Alliance (EIA), and as such should be recognized by one of ordinary skill in the art. For instance, such material may include a ceramic. Such materials may include a pervoskite, such as barium titanate and related solid solutions (e.g., barium-strontium titanate, barium calcium titanate, barium zirconate titanate, barium strontium zirconate titanate, barium calcium zirconate titanate, etc.), lead titanate and related solid solutions (e.g., lead zirconate titanate, lead lanthanum zirconate titanate), sodium bismuth titanate, and so forth. In one particular embodiment, for instance, barium strontium titanate (“BSTO”) of the formula BaₓSr₁₋ₓTiO₃ may be employed, wherein x is from 0 to 1, in some embodiments from about 0.15 to about 0.65, and in some embodiments, from about from 0.25 to about 0.6. Other suitable perovskites may include, for instance, BaₓCa₁₋ₓTiO₃ where x is from about 0.2 to about 0.8, and in some embodiments, from about 0.4 to about 0.6, PbₓZr₁₋ₓTiO₃ (“PZT”) where x ranges from about 0.05 to about 0.4, lead lanthanum zirconium titanate (“PLZT”), lead titanate (PbTiO₃), barium calcium zirconium titanate (BaCaZrTiO₃), sodium nitrate (NaNO₃), KNbO₃, LiNbO₃, LiTaO₃, PbNb₂O₆, PbTa₂O₆, KSr(NbO₃) and NaBa₂(NbO₃)₅KHb₂PO₄. Still additional complex perovskites may include A[B1_{1/3}B2_{2/3}]O₃ materials, where A is BaₓSr₁₋ₓ (x can be a value from 0 to 1); B1 is Mg_{y}Zn_{1-y} (y can be a value from 0 to 1); B2 is Ta_{z}Nb_{1-z} (z can be a value from 0 to 1). In one particular embodiment, the dielectric material may comprise a titanate.

As used herein, “formed over” may refer to a layer that is directly in contact with another layer. However, intermediate layers may also be formed therebetween. Additionally, when used in reference to a bottom surface, “formed over” may be used relative to an exterior surface of the component. Thus, a layer that is “formed over” a bottom surface may be closer to the exterior of the component than the layer over which it is formed.

The passivation layer of the capacitor can be formed over at least a portion of a surface of the substrate. The passivation layer may cover and protect the substrate from a deposition process (e.g., electroplating) that is used to form a conductive layer over the surface of the substrate. The passivation layer may be formed from a variety of suitable materials, including polymer materials. For example, in some embodiments, the passivation layer may be or include polyimide. In some embodiments, the passivation layer(s) may include at least one of silicon oxynitride, Al₂O₃, SiO₂, Si₃N₄, benzocyclobutene, or glass. The substrate and/or the passivation layer may be formed from a variety of inorganic materials such as glass, ceramic, or a glass-ceramic mixture. As described above, the substrate may include silicon oxynitride, silicon oxide, silicon, alumina, sapphire, and/or another suitable material.

In some embodiments, the passivation layer may be formed by depositing a paste (e.g., a glass paste, glass-ceramic paste, etc.) followed by a firing step. Any suitable process, however, may be used to form the passivation layer.

The first conductive layer of the capacitor can be formed over at least a portion of the passivation layer. The first conductive layer can be free of direct contact and/or direct electrical connection with the substrate. In an exemplary configuration, the conductive material from which the first conductive layer is formed may be electroplated over the passivation layer. Other methods for depositing the conductive material may also be employed as would be recognized by those of ordinary skill in the art.

The capacitor can also include an additional or a second conductive layer. In some embodiments, the second conductive layer can be formed over a second surface of the substrate, which is opposite the first surface of the substrate (over which are formed the passivation layer and the first conductive layer). Further, in some embodiments, a second passivation layer may be formed over at least a portion of the second surface of the substrate, and the second conductive layer may be formed over the second passivation layer such that the second passivation layer is disposed between the second conductive layer and the substrate. As described above with respect to the passivation layer formed between the first conductive layer and the substrate, the second passivation layer may be formed by depositing a paste (e.g., a glass paste, glass-ceramic paste, etc.) followed by a firing step, although any suitable process may be used to form the second passivation layer. Moreover, the second passivation layer may be formed from a variety of suitable materials, including polymer materials. For example, in some embodiments, the second passivation layer may be or include polyimide and/or may be or include at least one of silicon oxynitride, Al₂O₃, SiO₂, Si₃N₄, benzocyclobutene, glass, ceramic, or a glass-ceramic mixture.

The conductive layers may be formed from any of a variety of different metals as is known in the art. The conductive or electrode layers may be made from a metal, such as a conductive metal. The conductive materials may include precious metals (e.g., silver, gold, palladium, platinum, etc.), base metals (e.g., copper, tin, nickel, chrome, titanium, tungsten, etc.), and so forth, as well as various combinations thereof. The conductive layers or electrodes may also be made of a low resistive material, such as silver, copper, gold, aluminum, palladium, etc. In one particular embodiment, the conductive layers may comprise nickel or an alloy thereof.

One or more protective layers can be formed over the substrate and/or the passivation layer(s). For example, one or more protective layers can be formed over the first surface and/or the second surface of the substrate. As another example, one or more protective layers can be formed over the first passivation layer (formed over the first surface of the substrate) such that the first conductive layer is formed over the one or more protective layers. In some embodiments, one or more protective layers similarly may be formed over the second passivation layer, such as between the second passivation layer and the second conductive layer. Example materials for the protective layer(s) include benzocyclobutene (BCB), polyimide, silicon oxynitride, alumina (Al₂O₃), silica (SiO₂), silicon nitride (Si₃N₄), epoxy, glass, or another suitable material.

Various thin-film techniques can be used to form thin-film layers of the capacitor. For instance, one or more of the first conductive layer, the second conductive layer, the first passivation layer, and the second passivation layer may be thin-film layers of the capacitor. Examples of such techniques that may be employed include chemical deposition (e.g., chemical vapor deposition), PECVD (Plasma Enhanced Chemical Vapor Deposition) processing, physical deposition (e.g., sputtering), or any other suitable deposition technique for forming thin-film elements. Additional examples include any suitable patterning technique (e.g., photolithography), etching, and any other suitable subtractive technique for forming thin-film elements.

The thin-film layers can have a range of thicknesses. For example, the thin-film layers can have thicknesses that can range in some embodiments from about 0.001 micrometers (microns) to about 100 microns, in some embodiments from about 0.0375 microns to about 40 microns, in some embodiments from about 0.1 microns to about 30 microns, in some embodiments from about 0.2 microns to about 20 microns in some embodiments from about 0.4 microns to about 10 microns. For instance, in some embodiments, the resistive layer may have a thickness less than about 10 microns, in some embodiments less than about 8 microns, in some embodiments less than about 6 microns, and in some embodiments less than about 4 microns.

The conductive layers can be plated over the respective passivation layer. For example, where a first passivation layer is formed over the first surface of the substrate, a first conductive layer can be plated over the first passivation layer. In embodiments also including a second passivation layer formed over the second surface of the substrate, a second conductive layer can be plated over the second passivation layer.

The conductive layers may be formed such that each conductive layer is a thin-film plating of a metal. Such thin-film plating can be formed by depositing a conductive material, such as a conductive metal, on a passivation layer. A plated conductive layer or electrode may be formed by techniques known in the art, such as electroless plating, electrolytic plating, or combinations thereof. When multiple layers are used to form an electrode, the electrode may include an electroplated layer and an electroless plated layer. For instance, electroless plating may first be employed to deposit an initial layer of material. The plating technique may then be switched to an electrochemical plating system which may allow for a faster buildup of material. When forming the plated conductive layer(s) or electrode(s) with either plating method, at least a portion of the capacitor is subjected to a plating solution. By subjecting, in one embodiment, the capacitor may be dipped into the plating solution.

The plating solution used in a plating process may include a conductive material, such as a conductive metal. For instance, the plating solution may be a nickel sulfamate bath solution or other nickel solution such that the plated layer and external terminal comprise nickel. Alternatively, the plating solution may be a copper acid bath or other suitable copper solution such that the plated layer and external terminal comprise copper. Additionally, it should be understood that the plating solution may contain other additives as generally known in the art. For instance, the additives may include other organic additives and media that can assist in the plating process. Additionally, additives may be employed to employ the plating solution at a desired pH level. In one embodiment, resistance-reducing additives may be employed in the solutions to assist with complete plating coverage and bonding of the plating materials to the capacitor. The capacitor may be exposed, submersed, or dipped in the plating solution for a predetermined amount of time. The exposure time is not necessarily limited but may be for a sufficient amount of time to allow for enough plating material to deposit in order to form the plated layer. In this regard, the time should be sufficient for allowing the formation of a continuous layer on the respective surface of the substrate.

The difference between electrolytic plating and electroless plating is that electrolytic plating employs an electrical bias, such as by using an external power supply. The electrolytic plating solution may be subjected typically to a high current density range, for example, ten to fifteen amp/ft² (rated at 9.4 volts). A connection may be formed with a negative connection to the capacitor requiring formation of the plated terminals and a positive connection to a solid material (e.g., Cu in Cu plating solution) in the same plating solution. That is, the capacitor is biased to a polarity opposite that of the plating solution. Using such method, the conductive material of the plating solution is attracted to metal already disposed on the substrate. For example, as previously described, an initial amount of metal may be deposited on the substrate using an electroless process and the remaining amount of metal for the conductive layer may be deposited using electrolytic plating.

Prior to submersing or subjecting the capacitor to a plating solution, various pre-treatment steps may be employed. Such steps may be conducted for a variety of purposes, including to catalyze, to accelerate, and/or to improve the adhesion of the plating materials to the initial metal deposit. Additionally, prior to plating or any other pretreatment steps, an initial cleaning step may be employed. This step may be employed to remove any oxide buildup that forms on the substrate and/or initial metal deposit. Component cleaning may be affected by full immersion in a pre-clean bath, such as one including an acid cleaner. In one embodiment, exposure may be for a pre-determined time, such as on the order of about 10 minutes. Cleaning may also alternatively be affected by chemical polishing or harperizing steps.

In addition, a step to activate the metal may be performed to facilitate depositing of the conductive materials. Activation can be achieved by immersion in palladium salts, photo patterned palladium organometallic precursors (via mask or laser), screen printed or ink-jet deposited palladium compounds or electrophoretic palladium deposition. It should be appreciated that palladium-based activation is presently disclosed merely as an example of activation solutions that often work well with activation for exposed portions formed of nickel or an alloy thereof. However, it should be understood that other activation solutions may also be utilized and thus are not necessarily limited. Also, in lieu of or in addition to the aforementioned activation step, the activation dopant may be introduced into the conductive material. For instance, when the conductive layer comprises nickel and the activation dopant comprises palladium, the palladium dopant may be introduced into the nickel ink or composition that forms the conductive layer(s). Doing so may eliminate the palladium activation step. It should be further appreciated that some of the above activation methods, such as organometallic precursors, also lend themselves to co-deposition of glass formers for increased adhesion to the generally ceramic body of the capacitor. When activation steps are taken as described above, traces of the activator material may often remain at the exposed conductive portions before and after plating.

Additionally, post-treatment steps after plating may also be employed as desired or necessary. Such steps may be conducted for a variety of purposes, including enhancing and/or improving adhesion of the materials. For instance, a heating (or annealing) step may be employed after performing the plating step. Such heating may be conducted via baking, laser subjection, UV exposure, microwave exposure, arc welding, etc.

Thus, as described above, the conductive layers employed in the capacitor may contain at least one plated layer. In one embodiment, the conductive layers may contain only one plated layer. However, it should be understood that the conductive layers may comprise a plurality of plating layers. For instance, the conductive layers or electrodes may comprise a first plating layer and a second plating layer. In addition, the conductive layers or electrodes may also comprise a third plating layer. Further, the materials of these plating layers may be any of the aforementioned and as generally known in the art. For instance, one plating layer, such as a first plating layer, may contain copper or an alloy thereof. Another plating layer, such as a second plating layer, may contain nickel or an alloy thereof. Alternatively, another plating layer, such as the second plating layer, may contain copper or an alloy thereof. Another plating layer, such as a third plating layer, may comprise tin, lead, gold, or a combination, such as an alloy. Alternatively, an initial plating layer may include nickel, following by plating layers of tin or gold. In another embodiment, an initial plating layer of copper may be formed and then a nickel layer.

In one embodiment, the initial or first plating layer may be a conductive metal (e.g., copper). This area may then be covered with a second layer containing a resistor-polymeric material for sealing. The area may then be polished to selectively remove resistive polymeric material and then plated again with a third layer containing a conductive, metallic material (e.g., copper). The aforementioned second layer above the initial plating layer may correspond to a solder barrier layer, for example, a nickel-solder barrier layer. In some embodiments, the aforementioned layer may be formed by electroplating an additional layer of metal (e.g., nickel or copper) on top of an initial electrolessly or electrolytically plated layer (e.g., plated copper). Other exemplary materials for layer the aforementioned solder barrier layer include nickel-phosphorus, gold, and silver. A third layer on the aforementioned solder-barrier layer may, in some embodiments, correspond to a conductive layer, such as plated Ni, Ni/Cr, Ag, Pd, Sn, Pb/Sn or other suitable plated solder. In addition, a layer of metallic plating may be formed followed by an electroplating step to provide a resistive alloy or a higher resistance metal alloy coating, for example, electroless Ni—P alloy over such metallic plating. It should be understood, however, that it is possible to include any metal coating as those of ordinary skill in the art will understand from the complete disclosure herewith. It should be appreciated that any of the aforementioned steps can occur as a bulk process, such as barrel plating, fluidized bed plating, and/or flow-through plating termination processes, all of which are generally known in the art. Such bulk processes enable multiple components to be processed at once, providing an efficient and expeditious electrode deposition process. This is a particular advantage relative to conventional electrode deposition methods, such as the printing of thick-film conductive or electrode layers that require individual component processing.

In some embodiments, the conductive layers may be formed such that the conductive layers are relatively thick. For instance, such conductive layers may be formed by applying a thick film strip of a metal to the substrate. Such metal may be in a glass matrix and may include silver or copper. As examples, such strip may be printed and fired onto the capacitor or may be deposited by dipping the capacitor in a liquid conductive material. Such application of thick film conductive layers may include any method generally known in the art (e.g., by a printing wheel for transferring a metal-loaded paste over the substrate). In some embodiments, additional layers may be plated over the one or more thick film conductive layers, using any suitable plating method as described herein.

The thick film conductive layers may have an average thickness of at least about 5 μm or microns, such as an average thickness of about 10 microns or more, about 20 microns or more, about 25 microns or more, about 35 microns or more, about 50 microns or more, or about 75 microns or more. The thick film conductive layers may have an average thickness of about 500 microns or less, such as about 300 microns or less, such as about 200 microns or less, such as about 150 microns or less, such as about 100 microns or less, such as about 80 microns or less. For instance, the thick film conductive layers may have an average thickness within a range of about 5 microns to about 150 microns, such as a range of about 10 microns to about 100 microns, such as a range of about 25 microns to about 75 microns. In one embodiment, the aforementioned thicknesses refer to the average thickness of the entire conductive portion or electrode of the capacitor that is applied or deposited on one surface of the capacitor, which may, for example, include applications of more than one layer of conductive material to achieve the first conductive layer or electrode on the first surface of the substrate and/or the second conductive layer or electrode on the second surface of the substrate. In another embodiment, the aforementioned thicknesses refer to the average thickness of a single layer of a conductive layer or electrode of the capacitor.

In some embodiments, the capacitor can be at least partially embedded in a circuit board, e.g., a printed circuit board (PCB) or the like. For instance, the capacitor may be disposed in an opening or cavity in a circuit board such that at least a portion of the capacitor is surrounded by the circuit board. A portion of the capacitor may protrude from or extend above a mounting surface of the circuit board, or, at most, an outermost surface of the capacitor may be co-planar with the circuit board mounting surface while the remainder of the capacitor is within the opening or cavity and surrounded by the circuit board. In at least some embodiments, the capacitor may be electrically connected to the circuit board, for example, through a via or other conductive pathway extending from the capacitor to a conductive area (e.g., a conductive layer, termination, or port) of the circuit board.

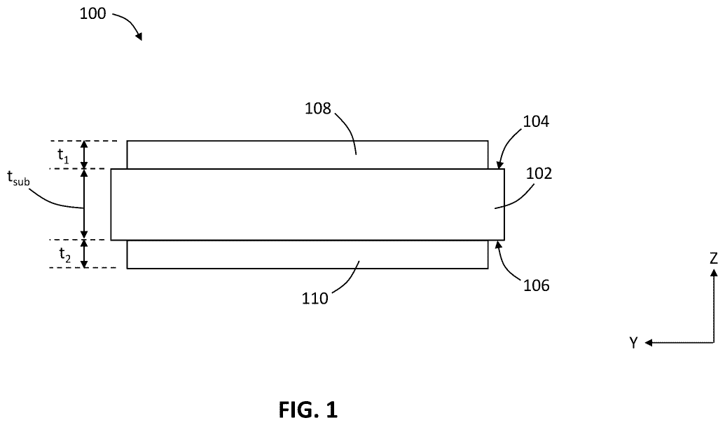

FIG. 1 is a side view of a single layer capacitor 100 according to aspects of the present disclosure. The single layer capacitor 100 may also be referred to herein as SLC 100 or capacitor 100. As shown in FIG. 1, the capacitor 100 can include a substrate 102 having a first surface 104 and a second surface 106 opposite the first surface 104 along a height or thickness direction Z. The substrate 102 can be formed from a dielectric material. In some embodiments, the dielectric material may have a relatively low dielectric constant (K), but in other embodiments, the dielectric material may have a relatively high dielectric constant.

The capacitor 100 can include a first conductive layer 108 formed over at least a portion of the first surface 104 of the substrate 102 and a second conductive layer 110 formed over at least a portion of the second surface 106 of the substrate 102. In some embodiments, the first conductive layer 108 is thick film conductive layer and has a first thickness t₁ that is at least about 5 microns. For example, the first conductive layer 108 may have a first thickness t₁ that is at least about 10 microns, a first thickness t₁ that is at least about 12 microns, a first thickness t₁ that is at least about 20 microns, a first thickness t₁ that is at least about 40 microns, a first thickness t₁ that is at least about 80 microns, a first thickness t₁ that is at least about 100 microns, a first thickness t₁ that is at least about 250 microns, or a first thickness t₁ that is at least about 500 microns. In some embodiments, the first thickness t₁ may be within a range of about 5 microns to about 150 microns, about 10 microns to about 100 microns, or about 25 microns to about 75 microns. The first conductive layer 108 can have other thicknesses as well.

Similarly, in at least some embodiments, the second conductive layer 110 is thick film conductive layer and has a second thickness t₂ that is at least about 5 microns. For example, the second conductive layer 110 may have a second thickness t₂ that is at least about 10 microns, a second thickness t₂ that is at least about 12 microns, a second thickness t₂ that is at least about 20 microns, a second thickness t₂ that is at least about 40 microns, a second thickness t₂ that is at least about 80 microns, a second thickness t₂ that is at least about 100 microns, a second thickness t₂ that is at least about 250 microns, or a second thickness t₂ that is at least about 500 microns. In some embodiments, the second thickness t₂ may be within a range of about 5 microns to about 150 microns, about 10 microns to about 100 microns, or about 25 microns to about 75 microns. The second conductive layer 110 can have other thicknesses as well.

Further, in at least some embodiments, the substrate thickness t_{sub} may be at least about 50 microns. For instance, the substrate thickness t_{sub} may be at least about 75 microns, at least about 100 microns, at least about 150 microns, at least about 250 microns, at least about 500 microns, or at least about 1000 microns. In some embodiments, a ratio of the substrate thickness t_{sub} to the first thickness t₁ may be at least 2, such as at least 2, at least 2.5, at least 3, or at least 4. Likewise, in some embodiments, a ratio of the substrate thickness t_{sub} to the second thickness t₂ may be at least 2, such as at least 2, at least 2.5, at least 3, or at least 4.

Referring still to FIG. 1, the substrate can have a substrate thickness t_{sub} along the height or thickness direction Z. In some embodiments, the substrate thickness t_{sub} can be greater than the thickness t₁, t₂ of at least one of the first conductive layer 108 or the second conductive layer 110. In other embodiments, the substrate thickness t_{sub} can be greater than the sum of the thicknesses t₁, t₂ of the first conductive layer 108 and the second conductive layer 110. In still other embodiments, the substrate thickness t_{sub} can be less than the thickness t₁, t₂ of at least one of the first conductive layer 108 or the second conductive layer 110.

It will be appreciated that the first conductive layer 108 and the second conductive layer 110 can be formed from any suitable conductive material as described elsewhere herein, and the substrate 102 can be formed from any suitable dielectric material as described elsewhere herein.

In some embodiments, the first conductive layer 108 and/or the second conductive layer 110 can extend over the entirety of the respective surface 104, 106 over which is formed the respective layer 108, 110. For instance, the first conductive layer 108 can extend to each edge defining the first surface 104 of the substrate 102 and/or the second conductive layer 110 can extend to each edge defining the second surface 106 of the substrate 102. Alternatively, the first conductive layer 108 and/or the second conductive layer 110 can be offset from one or more edges of the respective surface 104, 106, e.g., as shown in FIG. 1.

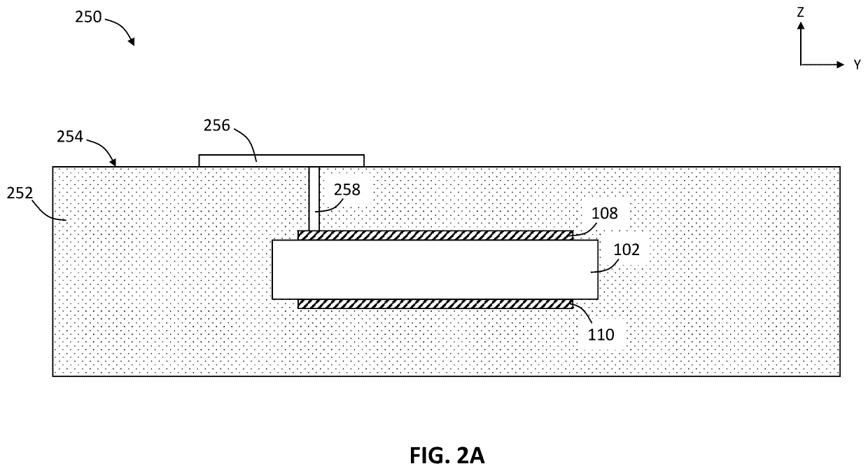

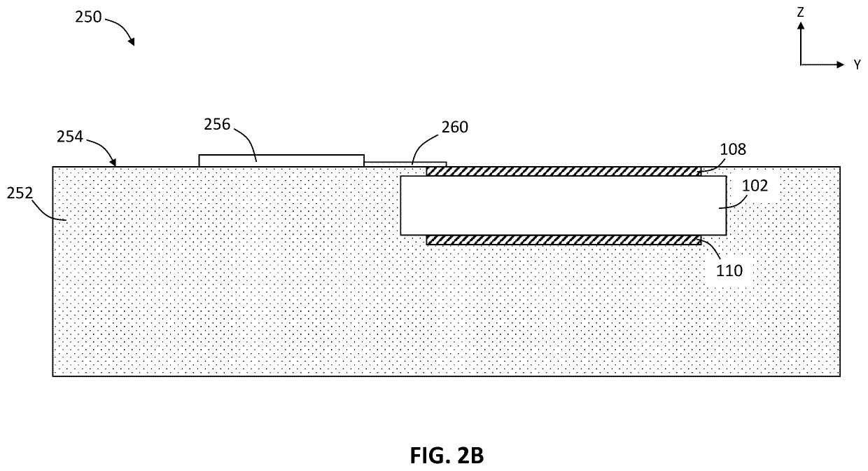

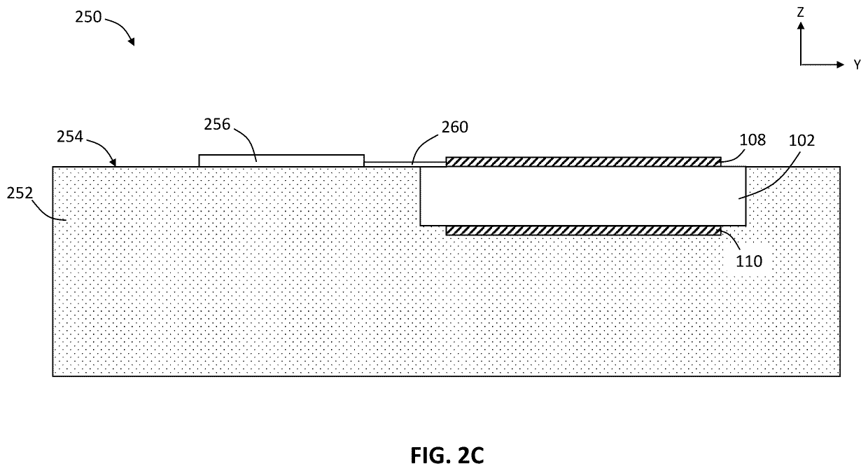

Referring now to FIGS. 2A through 2C, side views are illustrated of a circuit board 250 having the single layer capacitor 100 at least partially embedded therein according to aspects of the present disclosure. The circuit board 250 can include a circuit board substrate 252 having a mounting surface 254. In the embodiment shown in FIGS. 2A and 2B, the capacitor 100 is fully embedded in the circuit board substrate 252. More particularly, in the embodiment of FIG. 2A, the capacitor 100 is fully embedded within the circuit board substrate 252 such that the substrate 102, the first conductive layer 108, and the second conductive layer 110 of the capacitor 100 are each positioned below the mounting surface 254 of the circuit board 250 along the height or thickness direction Z. In the embodiment of FIG. 2B, the capacitor 100 is fully embedded within the circuit board substrate 252 such that the first conductive layer 108 of the capacitor 100 is co-planar with the mounting surface 254 of the circuit board 250. For example, an outermost surface of the first conductive layer 108 (i.e., the surface of the first conductive layer 108 opposite the first surface 104 of the substrate 102) can be co-planar with the mounting surface 254 of the circuit board 250 and the capacitor 100 still be considered fully embedded in the circuit board 250 because no portion of the capacitor 100 is extending above, beyond, or external to the circuit board 250. In other embodiments, the capacitor 100 can be partially embedded within the circuit board substrate 252 such that a portion of the capacitor 100 is disposed within the circuit board 250 and the remainder of the capacitor 100, such as the first conductive layer 108 and/or at least a portion of the substrate 102 of the capacitor 100, protrudes from or is external to the circuit board 250, e.g., along the height or thickness direction Z. For instance, in the embodiment of FIG. 2C, the capacitor 100 is partially embedded within the circuit board substrate 252 such that the first conductive layer 108 extends above the mounting surface 254 of the circuit board 250.

As further illustrated in FIGS. 2A through 2C, the capacitor 100 can be electrically connected with a conductive layer 256 of the circuit board 250. For instance, as shown in FIG. 2A, a via 258 can extend from the first conductive layer 108 of the capacitor 100 toward the mounting surface 254 of the circuit board 250 and connect to a conductive layer 256 formed over the mounting surface 254. As such, the via 258 of the circuit board 250 can electrically connect the capacitor 100 with the conductive layer 256 of the circuit board 250.

Referring to FIGS. 2B and 2C, in other embodiments, a conductive pathway 260 may electrically connect the capacitor 100 with the conductive layer 256 of the circuit board 250. As shown in FIGS. 2B and 2C, the conductive pathway 260 extends from the first conductive layer 108 of the capacitor 100 to the conductive layer 256 of the circuit board 250. As such, the conductive pathway 260 of the circuit board 250 can electrically connect the capacitor 100 with the conductive layer 256 of the circuit board 250.

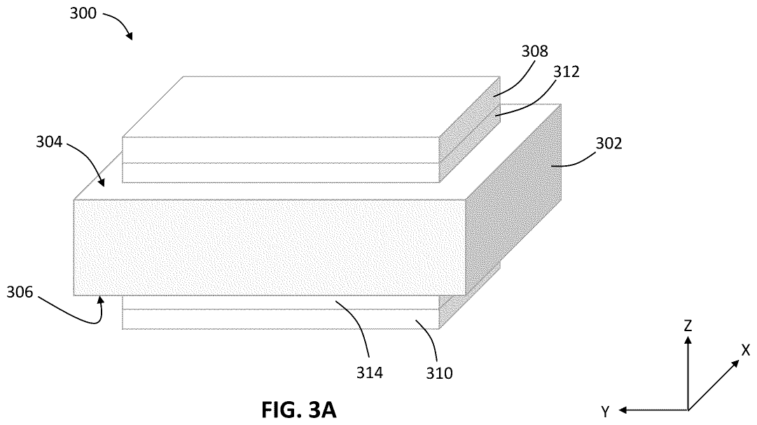

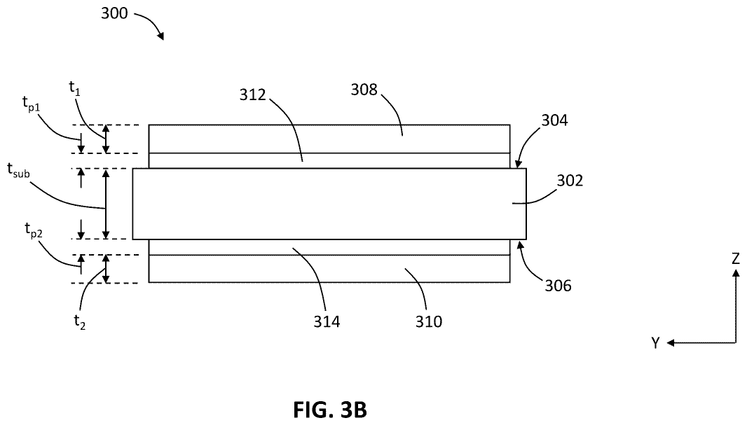

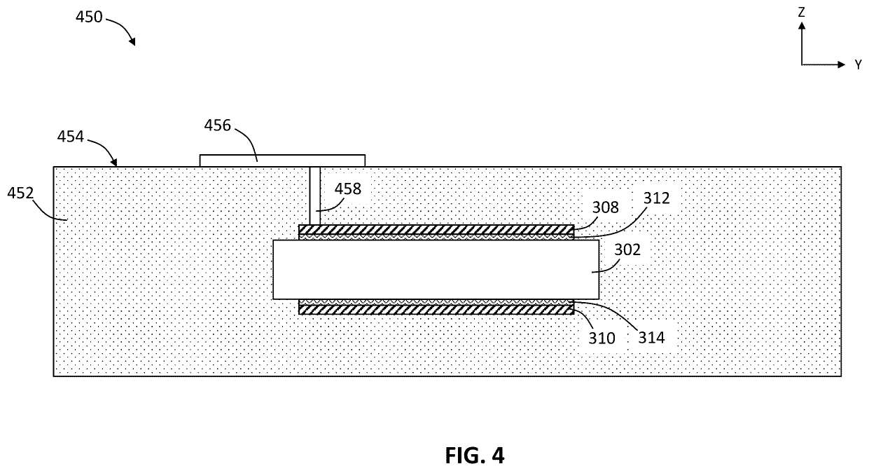

Turning now to FIGS. 3A, 3B, and 4, other embodiments of an embeddable single layer capacitor will be described. FIGS. 3A and 3B depict perspective and side views, respectively, of a single layer capacitor 300. Similar to the capacitor 100 described above, the capacitor 300 includes a substrate 302 having a first surface 304 and a second surface 306 opposite the first surface 304 along a height or thickness direction Z. The capacitor 300 also includes a first conductive layer 108 formed over at least a portion of the first surface 304 of the substrate 302 and a second conductive layer 310 formed over at least a portion of the second surface 306 of the substrate 302.

However, unlike the capacitor 100, the capacitor 300 shown in FIGS. 3A and 3B also includes a first passivation layer 312 and a second passivation layer 314. The first passivation layer 312 is formed over at least a portion of the first surface 304 of the substrate 302 such that the first passivation layer 312 is disposed between the substrate 302 and the first conductive layer 308. The second passivation layer 314 is formed over at least a portion of the second surface 306 of the substrate 302 such that the second passivation layer 314 is disposed between the substrate 302 and the second conductive layer 310. The passivation layers 312, 314 can facilitate forming the conductive layers 308, 310 using plating methods (such as electroless plating, electrolytic plating, etc.), which can increase the utility or functionality of the single layer capacitor.

In some embodiments, the first passivation layer 312 and/or the second passivation layer 314 can extend over the entirety of the respective surface 304, 306 over which is formed the respective passivation layer 312, 314. For instance, the first passivation layer 312 can extend to each edge defining the first surface 304 of the substrate 302 and/or the second passivation layer 314 can extend to each edge defining the second surface 306 of the substrate 302. Alternatively, the first passivation layer 312 and/or the second passivation layer 314 can be offset from one or more edges of the respective surface 304, 306, e.g., as shown in FIGS. 3A and 3B.

Similarly, the first conductive layer 308 can extend over the entirety of the first passivation layer 312, e.g., the first conductive layer 308 can extend to each edge of the first passivation layer 312, and/or the second conductive layer 310 can extend over the entirety of the second passivation layer 314, e.g., the second conductive layer 310 can extend to each edge of the second passivation layer 314. In other embodiments, the first conductive layer 308 and/or the second conductive layer 310 can be offset from one or more edges of the respective passivation layer 312, 314 over which is formed the respective conductive layer 308, 310.

As shown in FIG. 3B, the first conductive layer 308 may have a first thickness t₁ along the height or thickness direction Z, and the second conductive layer 310 may have a second thickness t₂ along the height or thickness direction Z. The first passivation layer 312 may have a first passivation thickness tₚ₁ along the height or thickness direction Z, and the second passivation layer 314 may have a second passivation thickness tₚ₂ along the height or thickness direction Z. Likewise, the substrate 302 may have a substrate thickness t_{sub} along the height or thickness direction Z.

In some embodiments, the first conductive layer 308 and the second conductive layer 310 may have approximately equal thicknesses t₁, t₂ , although in other embodiments, the first thickness t₁ of the first conductive layer 308 or the second thickness t₂ of the second conductive layer 310 may be greater than the other thickness t₁, t₂. Similarly, in various embodiments, the first passivation layer 312 and the second passivation layer 314 may have approximately equal passivation thicknesses tₚ₁, tₚ₂ or may have different passivation thicknesses tₚ₁, tₚ₂. In some embodiments, the first thickness t₁ of the first conductive layer 308 and/or the second thickness t₂ of the second conductive layer 310 may be greater than the first passivation thickness tₚ₁ and the second passivation thickness tₚ₂. In other embodiments, at least one of the first passivation thickness tₚ₁ or the second passivation thickness tₚ₂ may be greater than at least one of the first thickness t₁ or the second thickness t₂.

Further, the substrate thickness t_{sub} may be greater than the respective thickness of each individual layer 308, 310, 312, 314, and in some embodiments, the substrate thickness t_{sub} may be equal to or greater than the sum of the respective thicknesses of each individual layer 308, 310, 312, 314. However, in other embodiments, at least one of the first conductive layer 308, the second conductive layer 310, the first passivation layer 312, or the second passivation layer 314 may have a thickness that is greater than the substrate thickness t_{sub}, or in still other embodiments, the substrate thickness t_{sub} may be less than the sum of the respective thicknesses of each individual layer 308, 310, 312, 314. By way of example, in some embodiments, a ratio of the substrate thickness t_{sub} to the sum of the respective thicknesses of each individual layer 308, 310, 312, 314 may be at least about 1, such as at least about 1.5, at least about 2, at least about 2.5, at least about 3, or at least about 4. In other embodiments, however, a ratio of the substrate thickness t_{sub} to the sum of the respective thicknesses of each individual layer 308, 310, 312, 314 may be about 1 or less, such as about 0.9 or less, about 0.8 or less, about 0.75 or less, or about 0.7 or less.

In some embodiments, the first passivation thickness tₚ₁ and/or the second passivation thickness tₚ₂ may be at least about 50 Angstrom, such as at least about 75 Angstrom, at least about 100 Angstrom, or at least about 150 Angstrom. Further, the substrate thickness t_{sub} may be at least about 50 microns, such as at least about 75 microns, at least about 100 microns, at least about 150 microns, at least about 250 microns, at least about 500 microns, or at least about 1000 microns.

Referring now to FIG. 4, a side view is provided of a circuit board 450 having the single layer capacitor 300 at least partially embedded therein according to aspects of the present disclosure. The circuit board 450 can include a circuit board substrate 452 having a mounting surface 454. In the embodiment shown in FIG. 4, the capacitor 300 is fully embedded in the circuit board substrate 452. More particularly, in the embodiment of FIG. 4, the capacitor 300 is fully embedded within the circuit board substrate 452 such that the substrate 302, the first conductive layer 308, the first passivation layer 312, the second passivation layer 314, and the second conductive layer 310 of the capacitor 300 are each positioned below the mounting surface 454 of the circuit board 450 along the height or thickness direction Z. Although not illustrated herein, it will be appreciated that, in other embodiments, the capacitor 300 may be fully embedded within the circuit board substrate 452 such that the first conductive layer 308 of the capacitor 300 is co-planar with the mounting surface 454 of the circuit board 450, in a manner similar to that shown with respect to the capacitor 100 in FIG. 2B. In still other embodiments, the capacitor 300 can be partially embedded within the circuit board substrate 452 such that the first conductive layer 308, the first passivation layer 312, at least a portion of the substrate 302, the second passivation layer 314, and/or a portion of the second conductive layer 310 of the capacitor 300 extends above the mounting surface 454 of the circuit board 450 along the height or thickness direction Z, such as illustrated with respect to the capacitor 100 in FIG. 2C.

As further illustrated in FIG. 4, the capacitor 300 can be electrically connected with a conductive layer 456 of the circuit board 450. For instance, as shown in FIG. 4, a via 458 can extend from the first conductive layer 308 of the capacitor 300 toward the mounting surface 454 of the circuit board 450 and connect to a conductive layer 456 formed over the mounting surface 454. As such, the via 458 of the circuit board 450 can electrically connect the capacitor 300 with the conductive layer 456 of the circuit board 450. In other embodiments, a conductive pathway, e.g., a conductive pathway formed over the mounting surface 454 similar to the conductive pathway 260 of the circuit board 250 illustrated in FIGS. 2B and 2C, may electrically connect the capacitor 300 with the conductive layer 456 of the circuit board 450.

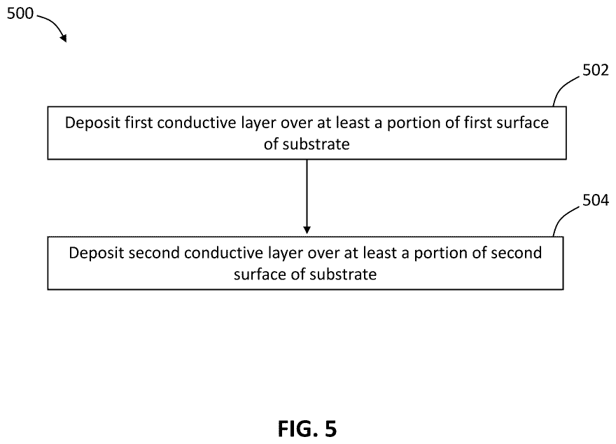

Referring now to FIG. 5, aspects of the present subject matter are directed to a method 500 for forming a single layer capacitor such as described herein. In general, the method 500 will be described herein with reference to the capacitor 100 of FIGS. 1, 2A, 2B, and 2C. However, it should be appreciated that the disclosed method 500 may be implemented with any suitable capacitor. In addition, although FIG. 5 depicts steps performed in a particular order for purposes of illustration and discussion, the methods discussed herein are not limited to any particular order or arrangement. One skilled in the art, using the disclosures provided herein, will appreciate that various steps of the methods disclosed herein can be omitted, rearranged, combined, and/or adapted in various ways without deviating from the scope of the present subject matter.

The method 500 can include (502) depositing a first conductive layer 108 over at least a portion of a first surface 104 of a substrate 102 of the capacitor 100. The first conductive layer 108 can have a thickness that is at least about 10 microns, such as at least about 20 microns, at least about 40 microns, or at least about 80 microns. The first conductive layer 108 may cover the entirety of the first surface 104 of the substrate 102 or may be offset from one or more edges defining a perimeter of the first surface 104. The first conductive layer 108 can be formed from any suitable electrically conductive material such as described herein.

The method 500 can also include (504) depositing a second conductive layer 110 over at least a portion of a second surface 106 of the substrate 102 of the capacitor 100. The second conductive layer 110 can have a thickness that is at least about 10 microns, such as at least about 20 microns, at least about 40 microns, or at least about 80 microns. The second conductive layer 110 may cover the entirety of the second surface 106 of the substrate 102 or may be offset from one or more edges defining a perimeter of the second surface 106. The second conductive layer 110 can be formed from any suitable electrically conductive material such as described herein.

It will be appreciated that (502) depositing the first conductive layer 108 and (504) depositing the second conductive layer 110 may include finish processing the capacitor 100 (the substrate 102 having the first conductive layer 108 and the second conductive layer 110 on opposing surfaces) using any appropriate method, such as firing, etc., to ensure adherence of the components of the capacitor 100 to one another and to prepare the capacitor 100 for use, such as in a circuit board 250 as described herein.

In some embodiments, depositing the first conductive layer 108 may include printing, such as screen printing, the first conductive layer 108 over at least a portion of the first surface 104 of the substrate 102. Similarly, in some embodiments, depositing the second conductive layer 110 may include printing, such as screen printing, the second conductive layer 110 over at least a portion of the second surface 106 of the substrate 102. It will be appreciated that screen printing the first conductive layer 108 and/or the second conductive layer 110 may include utilizing screen-printing techniques as known within the art. However, the conductive layer(s) 108, 110 may be applied to the substrate 102 by any known process, such as spin-coating, impregnation, casting, dropwise application, spray application, vapor deposition, sputtering, sublimation, knife-coating, painting, or printing (e.g., inkjet, screen, or pad printing).

In some embodiments, one or more additional layers of conductive material may be plated over an initial printed layer of conductive material to form the first conductive layer 108 and/or the second conductive layer 110 having a thickness of at least about 5 microns, such as about 10 microns or more. For instance, depositing the first conductive layer 108 may include printing a first layer of conductive material on the first surface 104 of the substrate 102, then plating at least one additional layer of conductive material over the first layer of conductive material. Likewise, depositing the second conductive layer 110 may include printing a second layer of conductive material on the second surface 106 of the substrate 102, then plating at least one additional layer of conductive material over the second layer of conductive material.

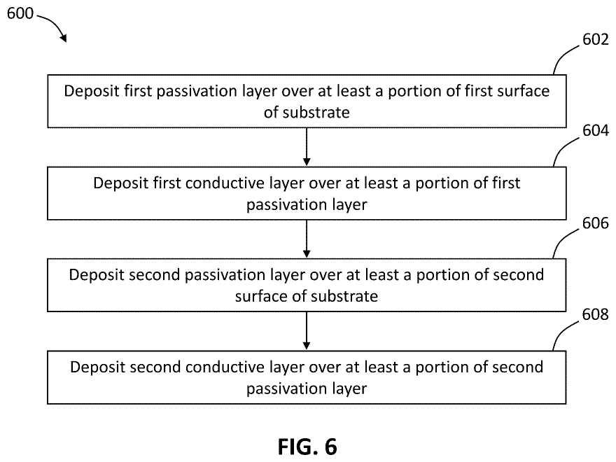

Turning now to FIG. 6, aspects of the present subject matter are directed to a method 600 for forming a single layer capacitor such as described herein. In general, the method 600 will be described herein with reference to the capacitor 300 of FIGS. 3A, 3B, and 4. However, it should be appreciated that the disclosed method 600 may be implemented with any suitable capacitor. In addition, although FIG. 6 depicts steps performed in a particular order for purposes of illustration and discussion, the methods discussed herein are not limited to any particular order or arrangement. One skilled in the art, using the disclosures provided herein, will appreciate that various steps of the methods disclosed herein can be omitted, rearranged, combined, and/or adapted in various ways without deviating from the scope of the present subject matter.

The method 600 can include (602) depositing a first passivation layer 312 over at least a portion of a first surface 304 of a substrate 302 of a single layer capacitor 300. The passivation layer 312 may be formed from a variety of suitable materials, including polymer materials and/or inorganic materials, such as glass or ceramic. For example, in some embodiments, the first passivation layer 312 may be or include polyimide. In some embodiments, the passivation layer(s) may include at least one of silicon oxynitride, Al₂O₃, SiO₂, Si₃N₄, benzocyclobutene, or glass.

The method 600 can include (604) depositing a first conductive layer 308 over at least a portion of the first passivation layer 312 such that the first passivation layer 312 is disposed between the first surface 304 of the substrate 302 and the first conductive layer 308. The first conductive layer 308 can be contained within a perimeter of the first passivation layer 312, e.g., the first conductive layer 308 can extend to the edges of the first passivation layer 312 and/or be offset from one or more edges of the first passivation layer 312. The first conductive layer 308 can be free of direct contact and/or direct electrical connection with the substrate 302.

Further, the method 600 can include (606) depositing a second passivation layer 314 over at least a portion of a second surface 306 of the substrate 302, where the second surface 306 is opposite the first surface 304 over which is formed the first passivation layer 312. Like the first passivation layer 312, the second passivation layer 314 may be formed from a variety of suitable materials, including polymer materials and/or inorganic materials, such as at least one of glass, ceramic, polyimide, silicon oxynitride, Al₂O₃, SiO₂, Si₃N₄, or benzocyclobutene.

Moreover, the method 600 can include (608) depositing a second conductive layer 310 over at least a portion of the second passivation layer 314 such that the second passivation layer 314 is disposed between the second surface 306 of the substrate 302 and the second conductive layer 310. The second conductive layer 310 can be contained within a perimeter of the second passivation layer 314, e.g., the second conductive layer 310 can extend to the edges of the second passivation layer 314 and/or be offset from one or more edges of the second passivation layer 314. The second conductive layer 310 can be free of direct contact and/or direct electrical connection with the substrate 302.

As described elsewhere herein, depositing the first and/or second passivation layers 312, 314 may include depositing a paste (e.g., a glass paste, glass-ceramic paste, etc.) on the substrate 302 then firing the substrate and paste to form the passivation layer(s) on the substrate 302. Any suitable process, however, may be used to form the passivation layer(s). It will be appreciated that the passivation layer(s) are deposited on the substrate 302, e.g., by depositing a paste and firing the paste and substrate 302 as described, prior to depositing the respective conductive layer 308, 310 over the respective passivation layer 312, 314.

Further, depositing the first and/or second conductive layers 308, 310 may include plating the first conductive layer 308 on the first passivation layer 312 and/or plating the second conductive layer 310 on the second passivation layer 314. The first and/or second conductive layers 308, 310 may be plated using electrolytic and/or electroless plating methods, as described above.

In any event, it will be appreciated that (602) depositing the first passivation layer 312, (604) depositing the first conductive layer 308, (606) depositing the second passivation layer 314, and (608) depositing the second conductive layer 310 may include finish processing the capacitor 300 (the substrate 302 having the first conductive layer 308 and the first passivation 312 on an opposite surface from the second conductive layer 310 and the second passivation layer 314) using any appropriate method, such as firing, etc., to ensure adherence of the components of the capacitor 300 to one another and to prepare the capacitor 300 for use, such as in a circuit board 450 as described herein.

### APPLICATIONS

The capacitor described herein is useful in a variety of applications, such as hybrid packaged components and filtering internal packaged semiconductors. Further, the capacitor may be useful in devices that process wideband radiofrequency signals, as the capacitor exhibits excellent performance at high frequencies, such as frequencies of 20 GHz or higher. Example devices include mobile devices (e.g., cell phones, tables etc.), cell phone towers, Receiver Optical Sub Assemblies (ROSA), Transmission Optical Sub Assembly (TOSA), and other RF communication devices. Such RF devices may be particularly useful in military and space applications.

These and other modifications and variations of the present invention may be practiced by those of ordinary skill in the art, without departing from the spirit and scope of the present invention. In addition, it should be understood that aspects of the various embodiments may be interchanged both in whole or in part. Further, those of ordinary skill in the art will appreciate that the foregoing description is by way of example only and is not intended to limit the invention so further described in such appended claims.

What is claimed is:

1. A circuit board comprising:
a circuit board substrate having a mounting surface; and
a single layer capacitor at least partially embedded within the circuit board substrate, the single layer capacitor comprising:
a substrate having a first surface opposite a second surface,
a first passivation layer formed over at least a portion of the first surface of the substrate,
a first conductive layer formed over at least a portion of the first passivation layer, and
a second conductive layer formed over at least a portion of the second surface of the substrate.

2. The circuit board of claim 1, the single layer capacitor further comprising:
a second passivation layer formed over at least a portion of the second surface of the substrate,
wherein the second conductive layer is formed over the second passivation layer such that the second passivation layer is disposed between the substrate and the second conductive layer.

3. The circuit board of claim 1, the single layer capacitor further comprising:
at least one via connected with the first conductive layer, the at least one via extending toward the mounting surface of the circuit board substrate.

4. The circuit board of claim 3, wherein a circuit board conductive layer is formed over the mounting surface, and wherein the at least one via electrically connects the circuit board conductive layer and the first conductive layer of the single layer capacitor.

5. The circuit board of claim 1, wherein the single layer capacitor is fully embedded within the circuit board substrate such that the substrate, the first passivation layer, the first conductive layer, and the second conductive layer are each positioned below the mounting surface along a height direction.

6. The circuit board of claim 1, wherein the single layer capacitor is fully embedded within the circuit board substrate such that the first conductive layer is co-planar with the mounting surface.

7. The circuit board of claim 1, wherein the single layer capacitor is partially embedded within the circuit board substrate such that one or more of the substrate, the first passivation layer, the first conductive layer, or the second conductive layer extends above the mounting surface along a height direction.

8. A single layer capacitor comprising:
a substrate having a first surface and a second surface opposite the first surface;
a first passivation layer formed over at least a portion of the first surface of the substrate;
a first conductive layer formed over at least a portion of the first passivation layer; and
a second conductive layer formed over at least a portion of the second surface of the substrate.

9. The single layer capacitor of claim 8, further comprising:
a second passivation layer formed over at least a portion of the second surface of the substrate,
wherein the second conductive layer is formed over the second passivation layer such that the second passivation layer is disposed between the substrate and the second conductive layer.

10. A method for forming a single layer capacitor, the method comprising:
depositing a first passivation layer over at least a portion of a first surface of a substrate;
depositing a first conductive layer over at least a portion of the first passivation layer; and
depositing a second conductive layer over at least a portion of a second surface of the substrate, the second surface opposite the first surface.

11. The method of claim 10, further comprising:
depositing a second passivation layer over at least a portion of the second surface of the substrate such that the second passivation layer is disposed between the second surface of the substrate and the second conductive layer.

12. The method of claim 11, wherein the first passivation layer and the second passivation layer are deposited before depositing either of the first conductive layer or the second conductive layer, and wherein depositing the first passivation layer and depositing the second passivation layer comprises depositing a paste and firing the substrate with the paste deposited thereon.

13. The method of claim 12, wherein depositing the second conductive layer comprises plating the second conductive layer on the second passivation layer.

14. The method of claim 10, wherein depositing the first passivation layer comprises depositing a paste and firing the substrate with the paste deposited thereon.

15. The method of claim 14, wherein depositing the first conductive layer comprises plating the first conductive layer on the first passivation layer.
